(19) United States
(12) Patent Application Publication
(10) Pub. No.: US 2014/0376316 A1
(43) Pub. Date: Dec. 25, 2014

(54) PROGRAMMABLE MEMORY CELL AND DATA READ METHOD THEREOF

(71) Applicant: UNITED MICROELECTRONICS CORPORATION, HSINCHU (TW)

(72) Inventors: Shi-Wen CHEN, Kaohsiung City (TW); Hsin-Pang Lu, Hsinchu County (TW)

(73) Assignee: UNITED MICROELECTRONICS CORPORATION, HSINCHU (TW)

(21) Appl. No.: 13/924,615

(22) Filed: Jun. 23, 2013

(51) Int. Cl. G11C 7/14

(52) U.S. Cl. CPC G11C 7/14
USPC 365/189.02; 365/189.09

(57) ABSTRACT

A programmable memory cell includes a non-volatile memory unit, a reference current generator and a readout unit. The non-volatile memory unit is configured to be performed by a program operation, a read operation or an erase operation. The reference current generator is configured to generate a reference current; wherein a value of the reference current is dynamically modulated according to a count number of the program and erase operations performed on the non-volatile memory unit. The readout unit, electrically coupled to the non-volatile memory unit and the reference current generator, is configured to read a data stored in the non-volatile memory cell according to the reference current. A data read method applied to the aforementioned programmable memory cell is also provided.

### FIELD OF THE INVENTION

The present invention relates to a memory technique field, and more particularly to a programmable memory cell and a data read method thereof.

### BACKGROUND OF THE INVENTION

In a read/write unit of a multiple time programmable memory Cell (MTP Cell), it is necessary to build a reference current as a reference for the read/write unit to determine the state (0 or 1) of the read data from a memory unit. However, the reference current in a conventional MTP Cell has a constant value; thus, if the memory unit has been processed by a certain number of erase and program operations or has a high-temperature deterioration which may consequently lead to a resulting current having a dramatic shift of level while a read operation is being performed, the state of stored data may be determined mistakenly when the resulting current is getting close to the reference current and consequentially a poor durability of the MTP Cell is thereby resulted.

### SUMMARY OF THE INVENTION

An object of the present invention is to provide a programmable memory cell having enhanced durability.

Another object of the present invention is to provide a data read method for the aforementioned programmable memory cell and consequentially the programmable memory cell has enhanced durability.

The present invention provides a programmable memory cell, which includes a non-volatile memory unit, a reference current generator and a readout unit. The non-volatile memory unit is configured to be performed by a program operation, a read operation or an erase operation. The reference current generator is configured to generate a reference current; wherein a value of the reference current is dynamically modulated according to a count number of the program and erase operations performed on the non-volatile memory unit. The readout unit, electrically coupled to the non-volatile memory unit and the reference current generator, is configured to read a data stored in the non-volatile memory cell according to the reference current.

The present invention further provides a data read method applied to a programmable memory cell for being performed by a program operation, a read operation or an erase operation. The method includes steps of: dynamically modulating a value of a reference current according to a number of the program and erase operations performed on the non-volatile memory cell; and reading a data stored in the programmable memory cell according to the reference current.

In summary, by configuring the reference bit line of the reference current generator to be performed by the erase and program operations simultaneously as the memory unit does, the reference current outputted from the reference current generator is dynamically modulated according to the count number of the erase and program operations performed on the memory unit and consequentially the non-volatile programmable memory cell of the present invention has enhanced durability.

### BRIEF DESCRIPTION OF THE DRAWINGS

The present invention will become more readily apparent to those ordinarily skilled in the art after reviewing the following detailed description and accompanying drawings, in which:

FIG. 1 is a schematic view depicting functional layout of a non-volatile programmable memory cell in accordance with an embodiment of the present invention;

FIG. 2 is a schematic view depicting functional layout of a reference current generator used in a non-volatile programmable memory cell in accordance with a preferred embodiment of the present invention;

FIG. 3 is a schematic circuit diagram of the reference current generator shown in FIG. 2;

FIG. 4 is a flow chart schematically illustrating a data read method applied to a non-volatile programmable memory cell in accordance with an embodiment of the present invention; and

FIG. 5 is a schematic view depicting functional layout of a reference current generator used in a non-volatile programmable memory cell in accordance with another preferred embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

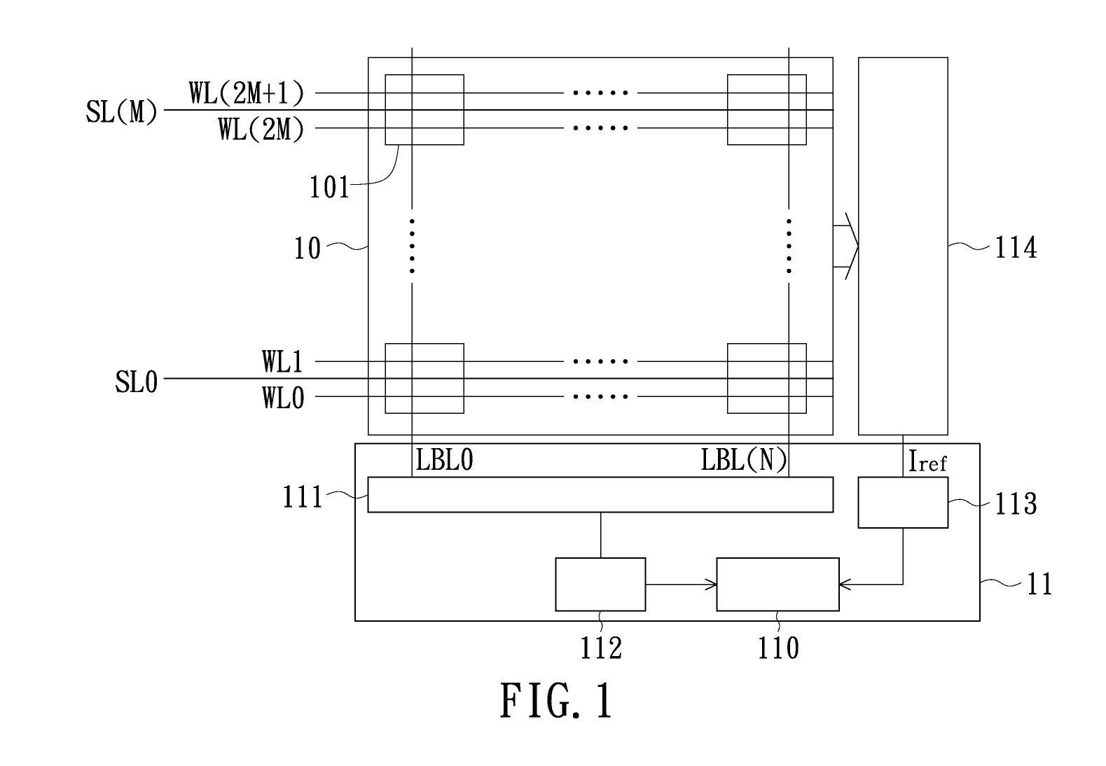

FIG. 1 is a schematic view of functional layout of a non-volatile programmable memory cell in accordance with an embodiment of the present invention. As shown, the non-volatile programmable memory cell in this embodiment mainly includes a memory unit 10, a readout unit 11 and a reference current generator 114. In addition, the non-volatile programmable memory cell in this embodiment further includes source lines SL0˜SL(M), word lines WL0˜WL,(2M+1) and bit lines LBL0˜LBL(N). The memory unit 10 includes a plurality of sub units 101 arranged in a matrix manner. The readout unit 11 includes a sense amplifier 110, a multiplexer 111 and two current-to-voltage converters 112, 113. The sense amplifier 110 is configured to perform a read operation on the sub units 101 of the bit lines LBL0˜LBL(N) through the multiplexer 111 and the current-to-voltage converter 112. The reference current generator 114 is configured to generate a reference current Iref. The current-to-voltage converter 113 is configured to convert the reference current Iref into a reference voltage SAR and provide the reference voltage SAR to the sense amplifier 110 as a reference while performing the read operation and thereby determining the state (0 or 1) of the data stored in the memory unit 10. Specifically, the value of the reference current Iref outputted from the reference current generator 114 is dynamically modulated according to a count number of the erase and program operations performed on the memory unit 10. Thus, the non-volatile programmable memory cell in this embodiment has enhanced durability.

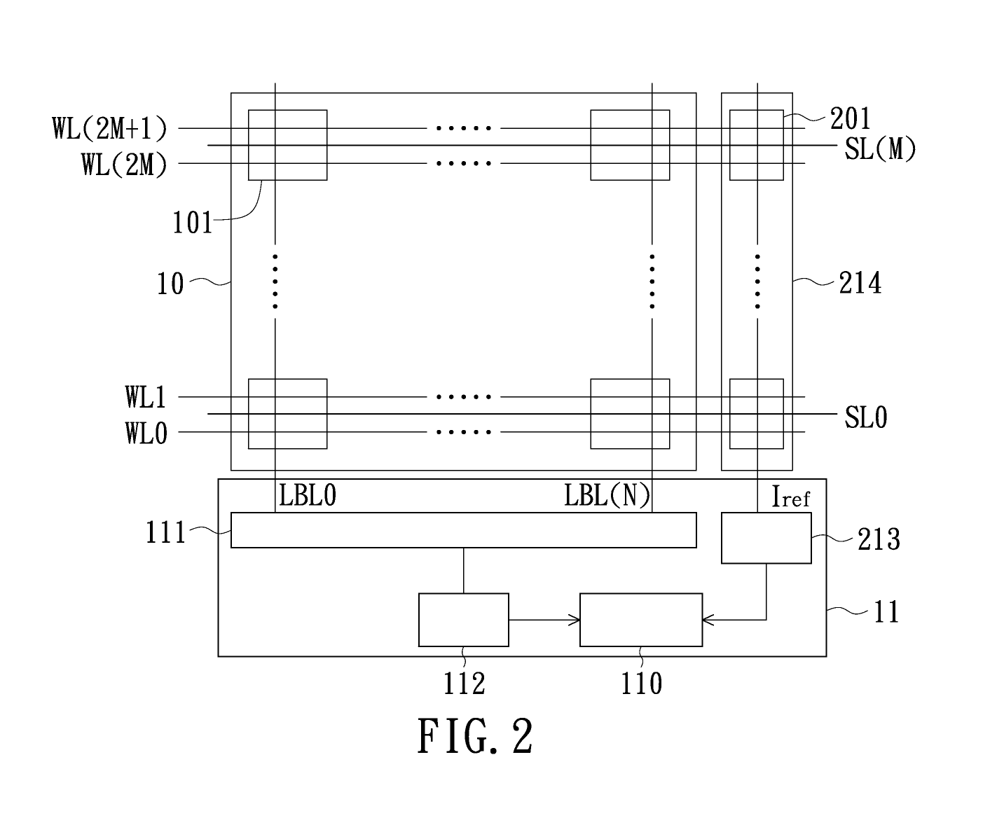

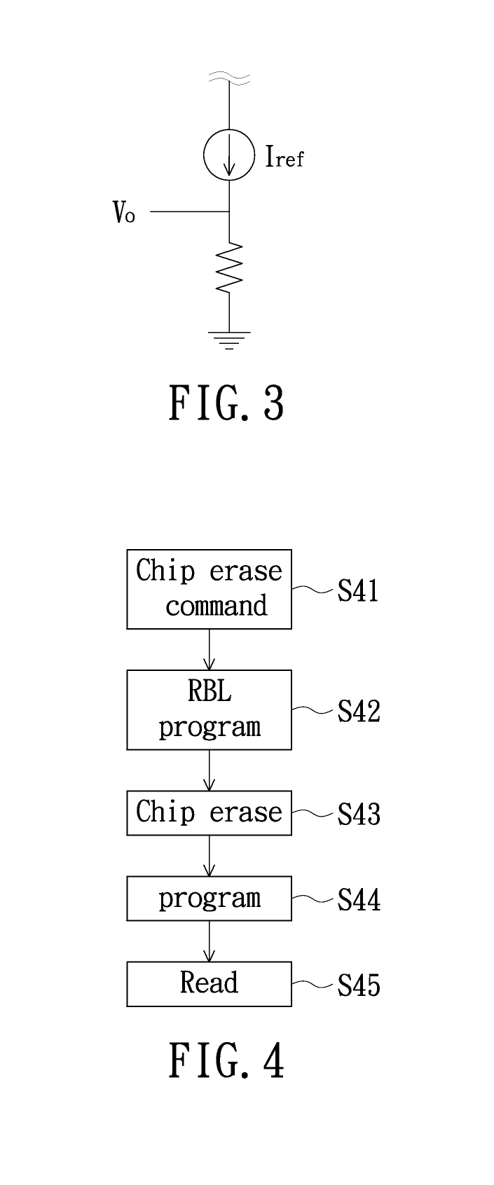

FIG. 2 is a schematic view of the functional layout of a reference current generator 214 used in a non-volatile programmable memory cell in accordance with a preferred embodiment of the present invention. The operations and functions of the memory unit 10 and the readout unit 11 have been described in FIG. 1, and no redundant detail is to be given herein. The reference current generator 214 in this embodiment employs a bit line unit having a circuit structure same as any bit line unit of the bit lines LBL0˜LBL(N) in the memory unit 10. In other words, the reference current generator 214 includes a reference bit line RBL, and the data stored in the sub units 201 of the reference bit line RBL is set to 1. Specifically, the current outputted from the bit line unit herein is referred to as the reference current Iref of the reference current generator 214. Then, the current-to-voltage converter 213 is configured to convert the reference current Iref into a reference voltage SAR and provide the reference voltage SAR to the sense amplifier 110 as a reference while performing the read operation, and thereby determining the state (0 or 1) of the data stored in the memory unit 10. The current-to-voltage converter 213 may have a circuit structure as illustrated in FIG. 3, and has a resistor serially coupled to ground and configured to result in the reference voltage crossed thereon.

First, the reference current Iref is converted into a voltage Vₒ. The reference voltage SAR is then obtained by subtracting the voltage Vₒ by a constant voltage value (for example 0.7V); that is, the reference voltage SAR=Vₒ-0.7V. It is to be noted that the constant voltage value (for example, 0.7V) herein is for making the reference voltage SAR and a readout voltage more distinguishable. Thus, even when the memory unit 10 has been processed by a certain number of erase and program operations or has undergone a high-temperature deterioration which may consequently lead to a resulting current having a dramatic shift of level (most likely a decreasing level) while a read operation is being performed, the non-volatile programmable memory cell in this embodiment still has enhanced durability if the reference current Iref has the similar floating manner.

FIG. 4 is a flow chart schematically illustrating a data read method applied to a non-volatile programmable memory cell in accordance with an embodiment of the present invention. Generally, the non-volatile programmable memory cell is configured to have the data stored therein set to 1 if the non-volatile programmable memory cell is not injected with electrons; thus, when a chip erase command is issued from an associated system (step S41), a program operation is first performed on the reference bit line RBL of the reference current generator 214 (step S42) so as to compensate for the previously-not-performed program operation; wherein the program operation performed on the reference bit line RBL (RBL program) may take about 160 μs. Then, a chip erase operation is performed on the memory unit 10 (step S43); wherein the chip erase operation may take about 100 ms. Then, a program operation for writing new data to the memory unit 10 is performed (step S44); wherein the program operation may take about 160 μs. Eventually, a read operation is performed on the memory unit 10 (step S45). Thus, by configuring the reference bit line RBL of the reference current generator 214 to be performed by the erase and program operations simultaneously as does the memory unit 10, the reference current Iref outputted from the reference current generator 214 is dynamically modulated according to the count number of the erase and program operations performed on the memory unit 10 and consequentially the non-volatile programmable memory cell in this embodiment has enhanced durability.

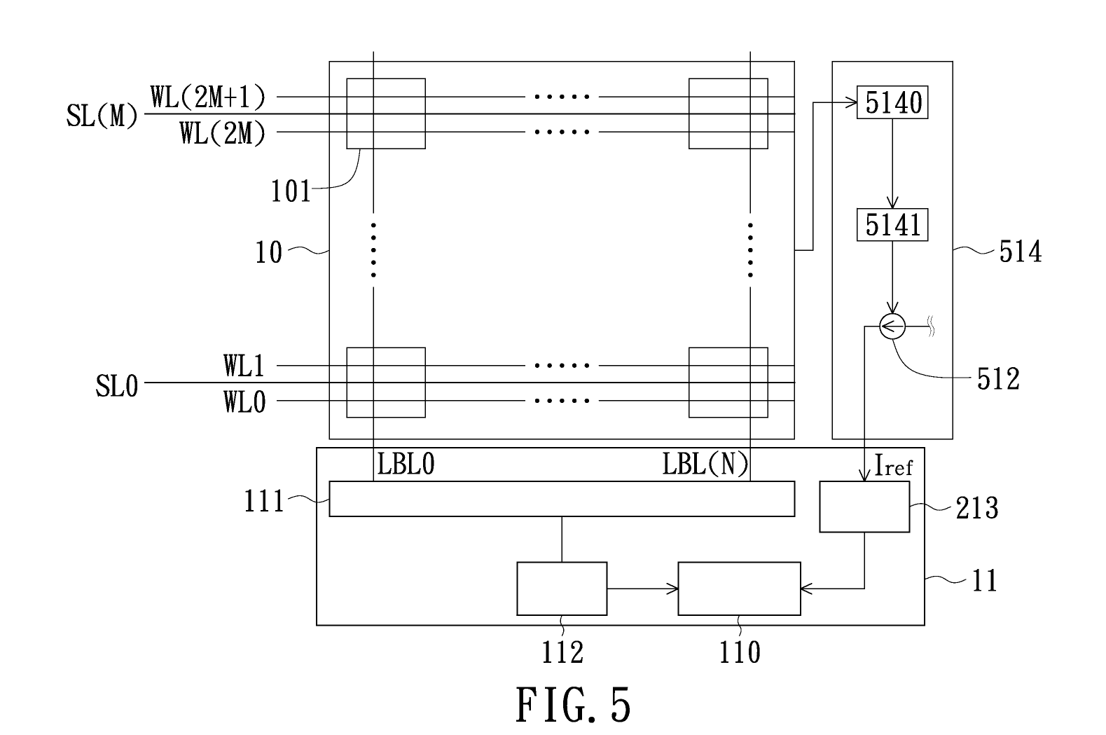

FIG. 5 is a schematic view of the functional layout of a reference current generator 514 used in a non-volatile programmable memory cell in accordance with another preferred embodiment of the present invention. The operations and functions of the memory unit 10 and the readout unit 11 have been described in FIGS. 1, 2, and no redundant detail is to be given herein. In this embodiment, a count number is obtained by counting the numbers of the erase and program operations performed on the memory unit 10, and the reference current outputted from the reference current generator 514 is dynamically modulated according to the count number. Specifically, the reference current generator 514 in this embodiment includes a cycle counter 5140, a look-up table 5141 and a current source 5142. The cycle counter 5140 is configured to generate the count number by counting the numbers of the erase operation and the program operation performed on the memory unit 10. The obtained count number is then compared with the look-up table 5141 to obtain a corresponding reference current value; wherein the look-up table 5141 may be built by experimental results. The current source 5142 is configured to generate a reference current Iref according to the reference current value. Same as the description associated with FIG. 3, the current-to-voltage converter 213 is configured to convert the reference current Iref into the reference voltage SAR. Thus, because the reference current Iref outputted from the reference current generator 514 is dynamically modulated according to the count number of the erase and program operations performed on the memory unit 10, the non-volatile programmable memory cell in this embodiment has enhanced durability.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A programmable memory cell, comprising:
a non-volatile memory unit for being performed by a program operation, a read operation or an erase operation;
a reference current generator configured to generate a reference current, wherein a value of the reference current is dynamically modulated according to a count number of the program and erase operations performed on the non-volatile memory unit; and
a readout unit, electrically coupled to the non-volatile memory unit and the reference current generator, configured to read a data stored in the non-volatile memory cell according to the reference current.

2. The programmable memory cell according to claim 1, wherein the non-volatile memory unit is a multiple time programmable memory cell.

3. The programmable memory cell according to claim 1, wherein the reference current generator comprises a bit line unit comprising a plurality sub units, a data stored in the sub units is set to 1 and a reference current is outputted from the bit line unit.

4. The programmable memory cell according to claim 3, wherein the readout unit comprises:
a multiplexer electrically coupled to the non-volatile memory unit;
a first current-to-voltage converter electrically coupled to the multiplexer and configured to convert a current outputted from the multiplexer into a voltage;
a second current-to-voltage converter electrically coupled to the reference current generator and configured to convert the reference current outputted from the reference current generator into a reference voltage; and
a sense amplifier electrically coupled to the first and second current-to-voltage converters, respectively, and configured to determine a state of a data stored in the non-volatile memory unit by comparing the voltage with the reference voltage.

5. The programmable memory cell according to claim 4, wherein the second current-to-voltage converter comprises a resistor serially coupled to ground and configured to result in the reference voltage crossed thereon.

6. The programmable memory cell according to claim 1, wherein the reference current generator comprises:
a cycle counter configured to accumulate the count number according to the number of the program and erase operations performed on the non-volatile memory unit;
a look-up table for providing a corresponding reference current value recorded therein according to the count number; and
a current source configured to generate a reference current according to the reference current value.

7. The programmable memory cell according to claim 6, wherein the readout unit comprises:
a multiplexer electrically coupled to the non-volatile memory unit;
a first current-to-voltage converter electrically coupled to the multiplexer and configured to convert a current outputted from the multiplexer into a voltage;
a second current-to-voltage converter electrically coupled to the reference current generator and configured to convert the reference current outputted from the reference current generator into a reference voltage; and
a sense amplifier electrically coupled to the first and second current-to-voltage converters, respectively, and configured to determine a state of a data stored in the non-volatile memory unit by comparing the voltage with the reference voltage.

8. The programmable memory cell according to claim 7, wherein the second current-to-voltage converter comprises a resistor serially coupled to ground and configured to result in the reference voltage crossed thereon.

9. A data read method applied to a programmable memory cell for being performed by a program operation, a read operation or an erase operation, the data read method comprising steps of
dynamically modulating a value of a reference current according to a count number of the program and erase operations performed on the non-volatile memory cell; and
reading a data stored in the programmable memory cell according to the reference current.

10. The data read method according to claim 9, wherein the step of dynamically modulating a value of a reference current according to a count number of the program and erase operations performed on the non-volatile memory cell comprises:
performing the program operation on a bit line unit in a reference current generator;
performing the erasing operation on the programmable memory cell;
performing the program operation on the programmable memory cell; and
configuring the reference current generator to output the reference current.

11. The data read method according to claim 9, wherein the step of dynamically modulating a value of a reference current according to a number of the program and erase operations performed on the non-volatile memory cell comprises:
accumulating a count number according to the number of the program and erase operations performed on the non-volatile memory unit;
obtaining a corresponding reference current value from a look-up table according to the count number; and
generating the reference current according to the reference current value.
